(19) United States
(12) Patent Application Publication
(10) Pub. No.: US 2009/0160442 A1
(43) Pub. Date: Jun. 25, 2009

(54) DOUBLE RESONANT TRANSMIT RECEIVE SOLENOID COIL FOR MRI

(75) Inventors: Peter Mazurkewitz, Hamburg (DE); Christoph Leussler, Hamburg (DE)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N. V., Eindhoven (NL)

(21) Appl. No.: 12/295,931

(22) PCT Filed: Mar. 15, 2007
(86) PCT No.: PCT/US07/64044

§ 371 Date: Oct. 3, 2008

Related U.S. Application Data
(60) Provisional application No. 60/744,292, filed on Apr. 5, 2006.

(51) Int. Cl. G01R 33/36; G01R 33/34

(52) U.S. Cl. 324/318

(57) ABSTRACT

A magnetic resonance system (8) comprises a radio frequency coil (36) which can resonate at least at first and second predetermined resonance frequencies. A tuning resonant circuit (110, 132) is serially coupled to the radio frequency coil (36). The tuning resonant circuit (110, 132) includes tuning components (Cp, Lp; Cp, Ch, Lh). Values of the tuning components (Cp, Lp; Cp, Ch, Lh) of the tuning circuit (110, 132) are selected such that a sensitivity profile of the radio frequency coil resonating at the first frequency substantially matches a sensitivity profile of the radio frequency coil resonating at the second frequency.

This application relates to the magnetic resonance arts. It finds particular application in magnetic resonance imaging observing ¹⁹F-¹H molecular imaging, and will be described with particular reference thereto. However, it also finds application more generally in multi-nuclear magnetic resonance imaging, magnetic resonance spectroscopy, and the like with various dipole pairs, such as carbon, phosphorous, and the like.

Magnetic resonance imaging scanners typically include a main magnet, typically superconducting, which generates a spatially and temporally constant magnetic field Bₒ through an examination region. A radio frequency (RF) coil, such as a whole-body coil, a head coil, and the like, and a transmitter have been tuned to the resonance frequency of the dipoles to be imaged in the Bₒ field. The coil and transmitter have often been used to excite and manipulate these dipoles. Spatial information has been encoded by driving the gradient coils with currents to create magnetic field gradients in addition to the Bₒ field across the examination region in various directions. Magnetic resonance signals have been acquired by the same or separate receive-only RF coil, demodulated, filtered and sampled by an RF receiver and finally reconstructed into an image on some dedicated or general-purpose hardware.

Double resonant ¹⁹F and ¹H magnetic resonance imaging or spectroscopy provides different kinds of metabolic information. For example, the ¹⁹F magnetic resonance imaging has a high potential for detection and direct quantification of fluorine-labeled tracers and drugs in the field of molecular imaging. The combination with ¹H magnetic resonance imaging provides associated anatomical information for localization prior to ¹⁹F imaging.

In one approach, ¹⁹F-¹H magnetic resonance imaging is performed using a double-tuned birdcage coil with a separate receiver channel for each frequency, one receiver tuned to image hydrogen (¹H imaging) and other receiver tuned to image fluorine (¹⁹F imaging). However, the sensitivity in either channel is substantially less than the sensitivity that may be achieved in a corresponding single resonant circuit. In addition, while the sensitivity can be optimized at one of the frequencies, the sensitivity of the remaining frequency is substantially less the circuit sensitivity at the optimized frequency.

In another approach two separate coils are used. One coil is tuned to the ¹⁹F frequency and the other coil is tuned to ¹H frequency. In this approach, too, the two tuned coils have different sensitivity profiles for each of the two imaged dipoles. It has been impractical to achieve the similar optimized sensitivities profiles for the two coils.

The present application provides improved apparatuses and methods which overcome the above-referenced problems and others.

In accordance with one aspect, a magnetic resonance system is disclosed. A radio frequency coil can resonate at least at first and second predetermined resonance frequencies. A tuning resonant circuit is serially coupled to the radio frequency coil which tuning resonant circuit includes tuning components. Values of the tuning components of the tuning circuit are selected such that a sensitivity profile of the radio frequency coil resonating at the first frequency substantially matches a sensitivity profile of the radio frequency coil resonating at the second frequency.

In accordance with another aspect, a magnetic resonance imaging method is disclosed. A tuning circuit which includes tuning components is serially coupled to a radio frequency coil which can resonate at least at first and second predetermined resonance frequencies. Values of tuning components of the tuning circuit are determined such that the radio frequency coil resonates at the first and second resonance frequencies and a sensitivity profile of the first frequency substantially matches a sensitivity profile of the second frequency.

In accordance with another aspect, a magnetic resonance coil system is disclosed. A radio frequency solenoid coil includes a conductor helically wound around a cylinder. The solenoid coil has an intrinsic inductance and first capacitors equidistantly connected between splits in the conductor. A resonant circuit is serially coupled to the conductor and includes a second capacitor, a third capacitor connected in parallel to the second capacitor, and an auxiliary inductance connected in series with the third capacitor. The first, second and third capacitors and the auxiliary inductance cooperate so that the radio frequency solenoid coil resonates at first and second predetermined resonance frequencies with substantially matching sensitivity profiles for the two frequencies.

One advantage resides in a multi-tuned coil with coordinated sensitivity profiles for each frequency.

Still further advantages of the described will be appreciated to those of ordinary skill in the art upon reading and understand the following detailed description.

The described may take form in various components and arrangements of components, and in various steps and arrangements of steps. The drawings are only for purposes of illustrating the preferred embodiments and are not to be construed as limiting the described.

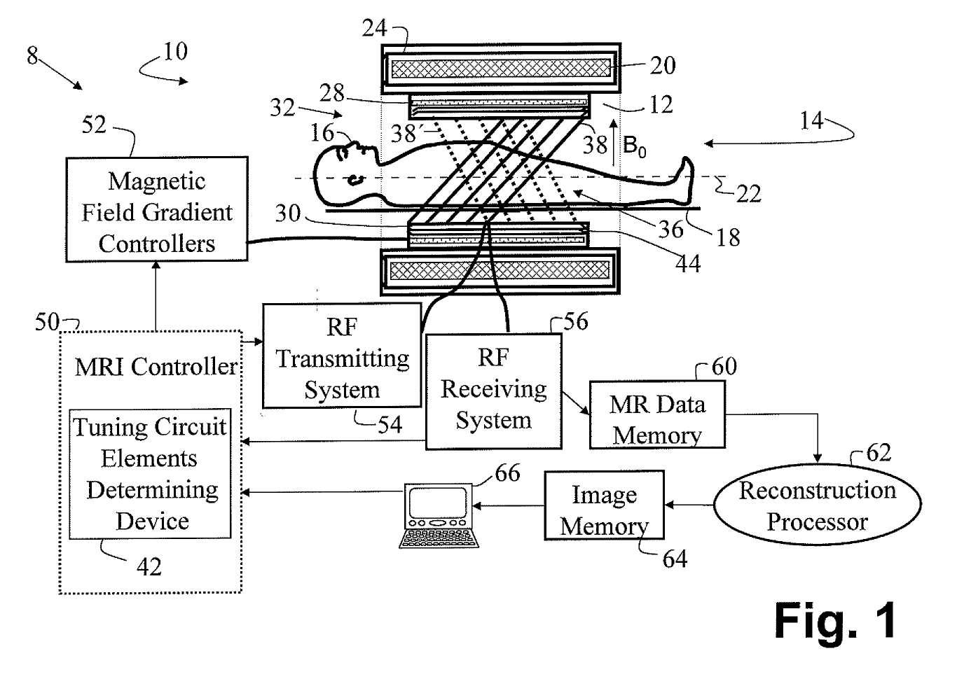

FIG. 1 is a diagrammatic illustration of a magnetic resonance imaging system;

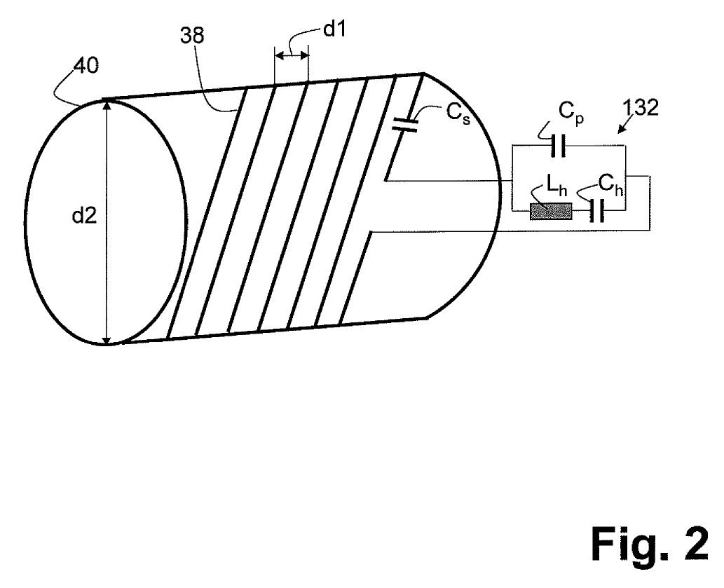

FIG. 2 is a diagrammatic illustration of a solenoid coil system;

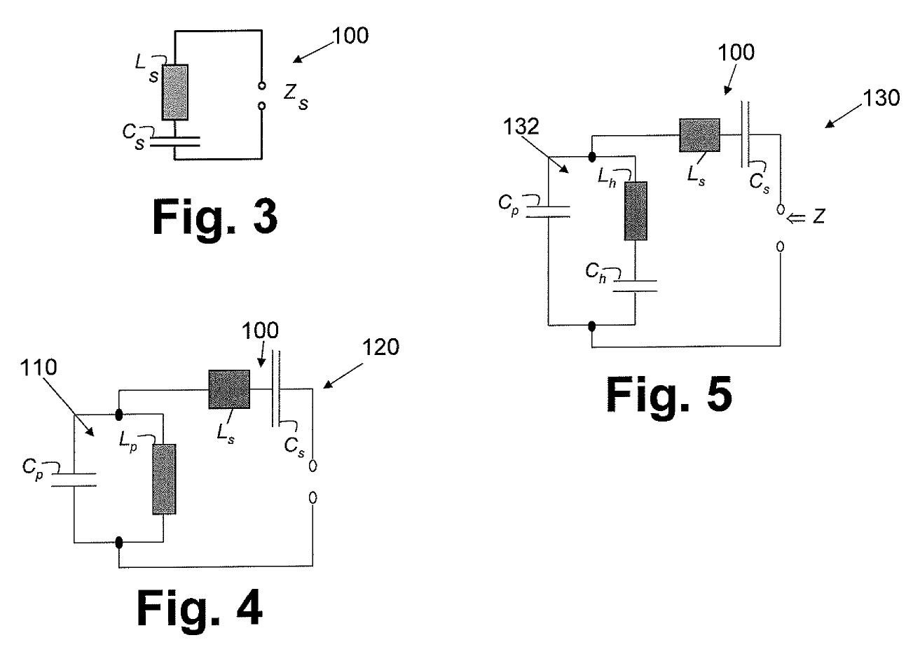

FIG. 3 is an electrical schematics of the solenoid coil system;

FIG. 4 is an electrical schematics of the solenoid coil system with an additional parallel circuit;

FIG. 5 is an electrical schematics of the coil system of FIG. 4 with an additional tuning capacitor; and

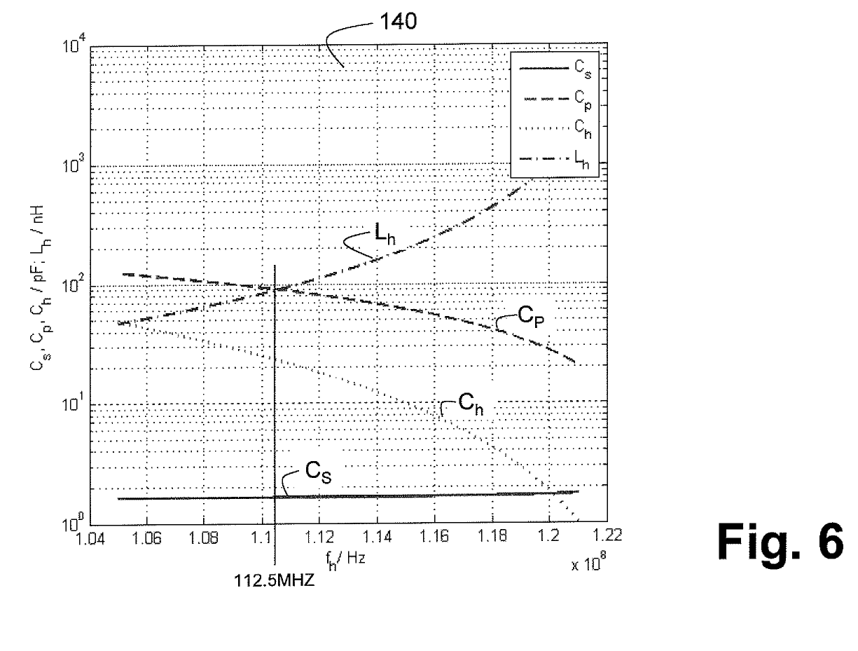

FIG. 6 shows a series of possible values for the tuning circuit components for achieving double resonance for ¹⁹F-H imaging.

With reference to FIG. 1, a magnetic resonance imaging system 8 includes a scanner 10 including a housing 12 defining an examination region 14, in which a patient or other imaging subject 16 is disposed on a patient or subject support or bed 18. A main magnet 20 disposed in the housing 12 generates a main magnetic field B₀ in the examination region 14. Typically, the main magnet 20 is a superconducting magnet surrounded by cryo shrouding 24; however, a resistive or permanent main magnet can also be used. Magnetic field gradient coils 28 are arranged in or on the housing 12 to superimpose selected magnetic field gradients on the main magnetic field within the examination region 14. A whole-body radio frequency coil 30, such as a stripline coil, SENSE coil elements, a birdcage coil, or the like, is arranged in the housing 12 to inject radio frequency excitation pulses into the examination region 14 and to detect generated magnetic resonance signals. A double resonant radio frequency (RF) coil system or arrangement 32 is disposed adjacent the examination region 14 to generate a magnetic field B₁ perpendicular to the main magnetic field B₀. The coil system 32 may be a solenoid coil, a saddle coil, a combination of the solenoid and birdcage coils, a combination of the solenoid and saddle coils, a combination of solenoid coils, and the like. In the exemplary embodiment, the coil system 32 includes a radio frequency coil 36 including a conductor or conductors 38 helically wound around a dielectric cylinder 40. Of course, the coil system 32 can have different geometries, such as elliptical. As discussed in detail below, a tuning circuit components determining device, processor, algorithm, manual calculations, or other means 42 determines proper values of elements or components of the tuning circuitry so that the coil system 32 resonates at two resonance frequencies and exhibits substantially matching sensitivity profiles for the two frequencies. A shield 44 shields the coils 30, 36 from the gradient coils and other surrounding structures.

With continuing reference to FIG. 1, a magnetic resonance imaging (MRI) controller 50 operates magnetic field gradient controllers 52 coupled to the gradient coils 28 to superimpose selected magnetic field gradients on the main magnetic field in the examination region 14, and also operates a radio frequency transmitting system 54 which is coupled to the radio frequency coil 36 to inject selected radio frequency excitation pulses ^{H}B₁, ^{F}B₁ at about a selected one or both of the magnetic resonance frequencies ^{H}fᵣₑₛ and ^{H}fᵣₑₛ into the examination region 14 for imaging. It is also contemplated that the radio frequency transmitting system 54 is coupled to the whole-body radio frequency coil 30. The radio frequency excitation pulses excite magnetic resonance signals in the imaging subject 16 that are spatially encoded by the selected magnetic field gradients. The imaging controller 50 also controls a radio frequency receiving system 56, which is inductively coupled with the coil 30, 36, to demodulate the received spatially encoded magnetic resonance signals at each resonance frequency. Of course, it is contemplated that the radio frequency receiving system 56 can be coupled with the coil 36 by other means such as capacitive coupling and the like. The received spatially encoded magnetic resonance data is stored in a magnetic resonance or MR data memory 60.

A reconstruction processor, algorithm, device, or other means 62 reconstructs the stored magnetic resonance data into a reconstructed image of the imaging subject 16 or a selected portion thereof lying within the examination region 14. The reconstruction processor 62 employs a Fourier transform reconstruction technique or other suitable reconstruction technique that comports with the spatial encoding used in the data acquisition. The reconstructed images are stored in an image memory 64, and can be displayed on a user interface 66, transmitted over a local area network or the Internet, printed by a printer, stored in a patient database, or otherwise utilized. In the illustrated embodiment, the user interface 66 also enables a radiologist or other user to interface with the imaging controller 50 to select, modify, or execute imaging sequences. In other embodiments, separate user interfaces are provided for operating the scanner to and for displaying or otherwise manipulating the reconstructed images.

The described magnetic resonance imaging system 10 is an illustrative example. In general, substantially any magnetic resonance imaging scanner can incorporate the disclosed radio frequency coils. For example, the scanner can be an open magnet scanner, a vertical bore scanner, a low-field scanner, a high-field scanner, or so forth. In the embodiment of FIG. 1, the coil 36 is used for both transmit and receive phases of the magnetic resonance sequence; however, in other embodiments, separate transmit and receive coils may be provided, either whole body or local, one or both of which may incorporate one or more of the radio frequency coil designs and design approaches disclosed herein.

With continuing reference to FIG. 1 and further reference to FIG. 2, the conductor or conductors 38 are wound or looped in a solenoid pattern around the dielectric cylinder 40 with a defined gap d1 between each two looped conductors 38. For a small imaging subject, an inner diameter d2 of the cylinder 40 is equal to about 70 mm and the gap d1 between the two conductors 38 is equal to about 8 mm. A first, intrinsic or serial inductance Lₛ of the solenoid coil 36 is measured and equal to about 1024 nH at 124 MHz. For further calculations, this value is assumed to be constant over a bandwidth of 20 MHz.

Equidistant capacitive splits are disposed along the conductor 38 to supply lumped first or serial capacitance or capacitor Cₛ in series between the solenoidal coil loops to avoid current inhomogeneities by propagation effects. For example, the lumped capacitance Cₛ includes 15 capacitors disposed equidistally along the conductor 38.

With continuing reference to FIG. 2 and further reference to FIG. 3, a circuitry of the coil 36 is represented by a first or serial resonant circuit 100 which comprises the first or serial inductance Lₛ, which represents the intrinsic inductance of the coil conductor 38, and the serial capacitance Cₛ which is coupled in series with the first inductance Lₛ and represents the lumped capacitance as discussed above. As an intrinsic resistance of the coil conductor 38 approaches 0Ω, the intrinsic resistance of the coil conductor 38 is neglected. A first or serial circuit impedance Zₛ of the opened circuit for the first resonant circuit 100 is:

$${Z}_{s} = j ( ω {L}_{s} - \frac{1}{ω {C}_{s}} ) , \qquad ( 1 )$$

where a parameter ω represents the dependence of the frequency f:

ω=2πf (2)

and an imaginary number j applies to

j²=−1 (3)

If a serial circuit resonance frequency ωₛ is determined by the first inductance and capacitance Lₛ, Cₛ as:

$${ω}_{s} ≡ \frac{1}{\sqrt{{L}_{s} {C}_{s}}} , then \qquad ( 4 )$$

the equation (1) for the serial circuit impedance Zₛ can be rewritten as:

$${Z}_{s} = j \frac{{ω}^{2} / {ω}_{s}^{2} - 1}{ω {C}_{s}} \qquad ( 5 )$$

As can be observed, the first impedance Zₛ behaves like a capacitor for frequencies that are lower than the serial circuit resonance frequency ωₛ, e.g. the imaginary part is negative, and like an inductance for frequencies that are higher than the serial circuit resonance frequency ωₛ, e.g. imaginary part is positive.

With continuing reference to FIG. 2 and further reference to FIG. 4, a second resonant circuit 110 is connected in series to the first resonant circuit 100. The second resonant circuit 110 includes a second or parallel inductance Lₚ, and a second or parallel capacitor or capacitance Cₚ, connected in parallel to the second inductance Lₚ. A second or parallel circuit impedance Zₚ of an opened circuit for the second resonant circuit 110 is:

$${Z}_{p} = j \frac{ω {L}_{p}}{1 - {ω}^{2} / {ω}_{p}^{2}} ; where \qquad ( 6 )$$

a parallel circuit resonance frequency ωₚ is determined by the second inductance and capacitance Lₚ, Cₚ as:

$${ω}_{2} ≡ \frac{1}{\sqrt{{L}_{p} {C}_{p}}} \qquad ( 7 )$$

As can be observed, the second impedance Zₚ behaves like an inductance for frequencies that are lower than the parallel circuit resonance frequency ωₚ, e.g. the imaginary part is negative, and like a capacitor for frequencies that are higher than the parallel circuit resonance frequency ωₚ, e.g. imaginary part is positive.

When the first and second circuits 100, 110 are combined into a third circuit 120, the third circuit 120 resonates at first and second resonance frequencies (o) and ω₂(ω₁<ω₂), which are necessary to magnetically resonate the isotope present in the subject 16, and can be calculated from the following dependencies:

Zₛ+Zₚ0| [symbol] ωₛωₚ=ω₁ω₂(8)

where Zₛ is the impedance of the first or serial circuit; and
Zₚ is the impedance of the second or parallel circuit.

Dependence between the first and second inductances Lₛ, Lₚ is:

$${L}_{p} = \frac{( {ω}_{p}^{2} - {ω}_{1}^{2} ) ( {ω}_{2}^{2} - {ω}_{p}^{2} )}{{ω}_{p}^{4}} {L}_{s} \qquad ( 9 )$$

In the equation (9) the intrinsic or first inductance Lₛ of the coil conductor 38 and the first and second resonance frequencies ω₁, ω₂ are predetermined parameters, e.g. the intrinsic inductance Lₛ can be measured in advance, and the first and second resonance frequencies ω₁, ω₂ are given as the known resonance frequencies for ¹⁹F-¹H or other dipole pair in the magnetic field B₀. As the second inductance Lₚ must be a positive value, the parallel circuit resonance frequency ωₚ must be greater than the first resonance frequency ω₁ and smaller than the second resonance frequency ω₂. Each value in such range results in a valid set of values for the second inductance Lₚ, second capacitor Cₚ, and first capacitor Cₛ.

If the first and second resonance frequencies ω₁, ω₂ have values that are substantially close to each other, as for example, ¹⁹F→120.24 MHz, and ¹H→127.74 MHz for 3 T imaging, the second inductance Lₚ becomes substantially smaller than the first or intrinsic inductance Lₛ. The value of the second inductance Lₚ has to be determined in the practical range. For example, as discussed above, for the intrinsic inductance Lₛ of the exemplary coil conductor 38 measured to about 1024 nH, the maximal value of the second inductance Lₚ is:

$${L}_{{p}_{max}} = 0.25 \frac{{( {ω}_{2}^{2} - {ω}_{1}^{2} )}^{2}}{{ω}_{1}^{2} {ω}_{2}^{2}} {L}_{s} = 3.754 n H , \qquad ( 10 )$$

which as a practicable matter, is difficult to achieve.

With reference to FIG. 5, a fourth or double resonant circuit 130 includes a tuning circuit 132 with an auxiliary or third capacitor Cₕ connected in series with a third or auxiliary inductance Lₕ. In one embodiment, the third inductance Lₕ is equivalent of the second or parallel circuit inductance and is equal to Lₚ. The fourth circuit 130 is resonant if the following equations are fulfilled:

$$\begin{matrix}\frac{{C}_{h}}{{C}_{p}} = \frac{( {ω}_{h}^{2} - {ω}_{1}^{2} ) ( {ω}_{h}^{2} - {ω}_{2}^{2} )}{{ω}_{h}^{2} ( {ω}_{s}^{2} - {ω}_{h}^{2} )} & ( 11 ) \\ \frac{{C}_{s}}{{C}_{h}} = \frac{{ω}_{h}^{2}}{{ω}_{s}^{2}} \frac{( {ω}_{1}^{2} - {ω}_{s}^{2} ) ( {ω}_{s}^{2} - {ω}_{2}^{2} )}{( {ω}_{h}^{2} - {ω}_{1}^{2} ) ( {ω}_{h}^{2} - {ω}_{2}^{2} )} & ( 12 )\end{matrix}$$

where a resonance frequency eel of the fourth circuit 130 is:

$${ω}_{h} ≡ \frac{1}{\sqrt{{L}_{h} {C}_{h}}} \qquad ( 13 )$$

A blocking frequency ω_{block} which provides high impedance is:

$${ω}_{block}^{2} = \frac{1}{{L}_{h}} ( \frac{1}{{C}_{p}} + \frac{1}{{C}_{h}} ) \qquad ( 14 )$$

The blocking frequency ω_{block} can be selected as:

ω_{block}²=ω₁ω₂ (15)

Dependence between the serial circuit resonance frequency ωₛ and the resonance frequency ωₕ of the fourth circuit 130 can be expressed as:

$$\begin{matrix}{ω}_{s}^{2} = \frac{( {ω}_{h}^{2} - {ω}_{1}^{2} ) ( {ω}_{h}^{2} - {ω}_{2}^{2} )}{{ω}_{1} {ω}_{2} - {ω}_{h}^{2}} + {ω}_{h}^{2} ; & {ω}_{h} < {ω}_{1} < {ω}_{s} < {ω}_{2}\end{matrix} \qquad ( 16 )$$

With reference to FIG. 6, from a graph 140, for each value of a frequency fₕ which is equal to:

$${f}_{h} = \frac{{ω}_{h}}{2 π} \qquad ( 17 )$$

a valid set of proper values for the auxiliary inductance Lₕ, auxiliary capacitance Cₕ, parallel circuit capacitance Cₚ and serial circuit capacitance Cₛ can be found so that the coil 36 is tuned to resonate at the exemplary 3 T Larmor-frequencies of ¹⁹F (120.23 MHz) and ¹H (127.73 MHz). E.g., each stack of values in each column gives a set of proper values for the tuning circuit components to achieve double resonance for 19F-¹H imaging. For example, for the value of frequency fₕ equal to about 112.5 MHz, the auxiliary inductance Lₕ can be equal to about 89.85 nH, the parallel circuit capacitance Cₚ can be equal to about 89.85 pF, the auxiliary capacitance Cₕ can be equal to about 23.07 pF and the serial circuit capacitance Cₛ can be equal to about 1.63 pF.

In the manner described above, a double resonant coil which has substantially similar sensitivity profiles for the two frequencies is built.

Optionally, a second set of coil conductors 38′ can be wound on the cylinder substantially perpendicular to the primary coils conductors 38 for quadrature excitation and reception. Rather than extending around the examination region 14, the solenoid coils can include loops above and below and/or on either side of the examination region. The coils can also be used with other coils, such as saddle coils. Moreover, the coils can be in addition to or in lieu of a birdcage coil.

In one embodiment, the coil system 32 can be electronically detuned by a tuning device such as PIN diode(s), making it possible to transmit/receive with the whole-body coil 30 without removing the ¹⁹F-¹H coil 36.

The application has been described with reference to the preferred embodiments. Modifications and alterations may occur to others upon reading and understanding the preceding detailed description. It is intended that the application be constructed as including all such modifications and alterations insofar as they come within the scope of the appended claims or the equivalents thereof.

1. A magnetic resonance system comprising:
a radio frequency coil which can resonate at least at first and second predetermined resonance frequencies; and
a tuning resonant circuit serially coupled to the radio frequency coil which tuning resonant circuit includes tuning components, values of the tuning components of the tuning circuit being selected such that a sensitivity profile of the radio frequency coil resonating at the first frequency substantially matches a sensitivity profile of the radio frequency coil resonating at the second frequency.

2. The system as set forth in claim 1, wherein the radio frequency coil includes:
a solenoid coil.

3. The system as set forth in claim 2, wherein the radio frequency solenoid coil includes a conductor with loops surrounding examination region.

4. The system as set forth in claim 3, further including:
an auxiliary conductor with loops which surround the examination region and are substantially perpendicular to the loops of the conductor for quadrature excitation and reception.

5. The system as set forth in claim 3, wherein the conductor includes helically arranged loops that define a gap between adjacent loops.

6. The system as set forth in claim 5, wherein the conductor includes a first capacitance, the solenoid coil has a first inductance and the tuning circuit (includes:
a second capacitance;
a third capacitance connected in parallel to the second capacitance; and
an auxiliary inductance connected in series with the third capacitance, the first second and third capacitances and the auxiliary inductance cooperate so that the radio frequency coil resonates at the first predetermined frequency corresponding to a first magnetic resonance frequency and at the second predetermined frequency corresponding to a second magnetic resonance frequency.

7. The system as set forth in claim 6, wherein the first capacitance and the first inductance define a series circuit which is connected in series with the tuning circuit, in the tuning circuit the auxiliary inductance and the third capacitance are connected in series with each other to define one leg, which leg is connected in parallel with the second capacitance.

8. The system as set forth in claim 6, wherein the values of the first capacitance are selected to tune the series circuit to behave as a capacitance at frequencies below the first resonance frequency and an inductance at frequencies above the first resonance frequency and the values of the second capacitance and auxiliary inductance are selected to tune the tuning circuit to behave as an inductance at frequencies below the second resonance frequency and a capacitance for frequencies above the second resonance frequency.

9. The system as set forth in claim 6, wherein the values of the second and third capacitances and the auxiliary inductance are selected to tune the radio frequency coil with the tuning circuit to be resonant at both the first and the second resonance frequencies.

10. The system as set forth in claim 6, further including:
a magnet which generates a main magnetic field through the examination region and wherein the first resonance frequency is the resonance frequency of fluorine and the second resonance frequency is the resonance frequency of hydrogen in the main magnetic field.

11. The system as set forth in claim 1, wherein the coil includes a first capacitance and a first inductance which define a series circuit which is connected in series with the tuning circuit.

12. The system as set forth in claim 11, wherein the tuning circuit includes:
a second capacitance; and
a second inductance connected in parallel to the second capacitance.

13. A magnetic resonance imaging method comprising:
serially coupling a tuning circuit which includes tuning components to a radio frequency coil which can resonate at least at first and second predetermined resonance frequencies; and
determining values of the tuning components of the tuning circuit such that the radio frequency coil resonates at the first and second resonance frequencies and a sensitivity profile of the first frequency substantially matches a sensitivity profile of the second frequency.

14. The method as set forth in claim 13, wherein the conductor is wound in a solenoid with an inherent inductance, a first capacitance is connected in series with the inherent inductance, the method including:
selecting a value for the first capacitance such that the serially connected inherent inductance and first capacitance behave like an inductance at frequencies above the first resonance frequency and a capacitance at frequencies below the first resonance frequency.

15. The method as set forth in claim 14, wherein the tuning circuit includes a second capacitance connected in parallel with at least an inductive element, the method including:
selecting values for the second capacitance and the inductive element such that the tuning circuit behaves as a capacitance at frequencies above the second resonance frequency and an inductance at frequencies below the second resonance frequency.

16. The method as set forth in claim 14, wherein the tuning circuit includes:
a second capacitance;
a third capacitance connected in parallel to the second capacitance; and
an auxiliary inductance connected in series with the third capacitance, the method including:
selecting values for the second and third capacitances and the auxiliary inductance such that the radio frequency coil resonates at the first and second predetermined frequencies.

17. The method as set forth in claim 16, further including:
selecting the values for the first, second, and third capacitances and the auxiliary inductance such that the first predetermined resonance frequency is a resonance frequency of fluorine and the second predetermined resonance frequency is a resonance frequency of hydrogen.

18. A magnetic resonance scanner including:
a main field magnet which generates a main magnetic field through an examination region;
a radio frequency coil for at least one of transmitting radio frequency signals into the examination region and/or receiving radio frequency signals from the examination region as first and second predetermined resonance frequencies; and
a tuning circuit having tuning components tuned by the method of claim 13.

19. A magnetic resonance coil system including:
a radio frequency solenoid coil which includes a conductor helically wound around a cylinder, the solenoid coil having an intrinsic inductance and first capacitors equidistantly connected between splits in the conductors; and
a resonant circuit serially coupled to the conductor including:
a second capacitor,
a third capacitor connected in parallel to the second capacitor, and
an auxiliary inductance connected in series with the third capacitor;
the first, second and third capacitors and the auxiliary inductance cooperate so that the radio frequency solenoid coil resonates at first and second predetermined resonant frequencies with substantially matching sensitivity profiles for the two frequencies.

20. A magnetic resonance imaging method for ¹⁹F-¹H by magnetic resonance imaging with the coil system of claim 19, the method comprising:
tuning the first, second, and third capacitors and the auxiliary inductor such that the first predetermined resonant frequency is a resonant frequency of in a magnetic field and the second resonant frequency is a resonant frequency in the magnetic field;
generating the magnetic field through an examination region inside the solenoid coil;
applying gradient magnetic fields across the examination region;
pulsing the solenoid coil in a frequency spectra encompassing each of the resonant frequencies of and to excite resonance in and dipoles in a subject in the examination region;
receiving resonance signals at the resonance frequencies of and with the solenoid coil; and
reconstructing the resonance signals into a image and the resonance signals into an image, the and images being inherently registered.
